(19) United States
(12) Patent Application Publication
(10) Pub. No.: US 2021/0216675 A1
(43) Pub. Date: Jul. 15, 2021

(54) FIXTURE OPTIMIZATION FOR A LIGHTING PLAN

(71) Applicant: CITELUM US, INC., Houston, TX (US)

(72) Inventors: Pierre Leboulleux, Houston, TX (US); Gaelle Malette, Houston, TX (US)

(21) Appl. No.: 16/743,891

(22) Filed: Jan. 15, 2020

(51) Int. Cl. G06F 30/13; G06F 30/12

(52) U.S. Cl. CPC G06F 30/13; G06F 30/12

(57) ABSTRACT

Examples herein describe systems and methods for providing a lighting plan. A planning server can identify roads within a designated area for providing lights as part of the lighting plan. The planning server can also organize segments of the roads into segment groups based on common features of the segments. The common features can include road dimensions and objects adjacent to the segments. The planning server can also assign lights to the segment groups based on the common features. The planning server can also display the lighting plan on a graphical user interface (“GUI”) based on the lights assigned to the segment groups.

### BACKGROUND

As cities become more complex, urban planning becomes increasingly important. Urban planning can include infrastructure design and development, such as transportation, communications, water management, and lighting. As cities grow and time passes, current infrastructure can become insufficient or outdated. For example, a sewage system designed for a certain number of people in a city may be insufficient if the population of the city doubles. Changes must then be made to update the infrastructure for the safety and well-being of residents and guests.

Lighting has become an important part of urban planning projects. Many different types of lights exist, including different colors and patterns. However, analyzing or replacing lighting infrastructure can be a difficult and lengthy process. Cities can have tens of thousands of lights, and each street or block may have its own unique lighting needs. Additionally, lighting today is available in a large variety of types, varying in brightness, color temperature, wattage, direction, etc. This can make planning lighting in a city extremely complex, and it can be nearly impossible to manually assess and plan for appropriate lighting updates and changes. Traditional methods cannot select the right lighting types for the right places in a timely manner.

For example, existing software does not include means for accurately planning lighting and other infrastructure needs in an urban environment. Although satellite imagery is available, current solutions do not visualize the finer details or correlations between lighting, infrastructure, and living conditions.

As a result, a need exists for a system that can help resolve lighting issues in cities, including determining where lighting changes and additions are needed. Moreover, a need exists for a system that can identify roads in a designated area, organize the roads into segment group based on common features, and resolve the lighting issues accordingly.

### SUMMARY

Examples described herein include systems and methods for providing lighting plans. A user device, such as a laptop, can connect with a planning server in an example. The planning server can determine a designated area for a lighting plan. The planning server can identify roads in the designated area and access object data with global positioning coordinates within the designated area. The object data can represent buildings, trees, and other three-dimensional structures. The roads can be cut into segments, such as 100-foot-long segments, based on a setting regarding segment granularity. The planning server can group roads and adjacent objects into segment groups within the designated area. The groups can be based on common features of the roads, objects, and demographic information for the segment. The planning server can also access a lighting database of different types of lights. For each common segment group, the planning server can determine a lighting numbers and types based on the features. The corresponding lights can be assigned to the segment groups.

In one example, the user device, such as a laptop or personal computer, can display a graphical user interface (“GUI”). A designated area can be selected or provided on the GUI. The planning server can then identify roads within the designated area. The planning server can determine one or more lighting plans for providing lights along the roads. As part of doing so, the planning server can organize segments of the roads into segment groups based on common features of the segments. For example, some road segments can have similar bends, similar widths and lanes, similar sidewalk arrangements, crime demographics, traffic demographics, and similar objects adjacent to the road. The objects can be, for example, buildings or trees that block off particular lighting angles.

The planning server can also assign lights to the segment groups based on common features of the segments. In one example, the road shape or objects of a grouped segment can determine a shape of light needed from a lighting fixture. Additionally, traffic or crime demographics can inform the color (e.g., cool frequency versus warm frequency) light needed. The common features of the segments can include road data such as the length, width, and curve for each segment. The adjacent objects can include neighboring group segments and objects adjacent to group segments. The relative contribution of neighboring segment groups and adjacent objects onto a given segment group can affect the lighting plan for fixtures within the given segment group. Further, the common features of the segments can include environmental data such as the traffic level. The traffic level can include pedestrians and vehicles moving within the segment groups. A segment group with a higher traffic level than other segment groups would require a different lighting plan to accommodate the greater traffic level. The environmental data can also include a level of crime identified for each segment group. A segment group with a greater level of crime would require a different lighting plan than another segment group with a less degree of crime.

The planning sever can determine the segments that are adjacent to each other when determining the lighting plans for each of the segments. In addition, the planning server can determine whether to put the lights on one side of the street or both sides of the street for each segment. The adjacent segments can enable the planning server to determine whether to place lights on one side or both sides of the street. In addition, depending on the object data or environmental data described above, the planning server can decide on whether to the intensity of the lights to be configured in the segment group. Accordingly, the planning server can also determine a maximum and minimum light intensity for the lights for each segment group using the using the object data from the nearby segment groups and the environmental data (crime and traffic levels).

The planning server can repeat the described steps for each of the segment groups. For example, after lights are provided for a segment group, the planning server can then repeat the process to provide lights for another segment group. When the planning server via the user device has provided each of the segment groups with lights, the process can end. The GUI can display the lighting plan based on the lights that are assigned to the segment groups. The common features can include road dimensions, objects adjacent to the segments, and environmental data.

The method can be described by instructions in a non-transitory, computer-readable medium. A processor can execute the instructions in a system.

Both the foregoing general description and the following detailed description are exemplary and explanatory only and are not restrictive of the examples, as claimed.

### BRIEF DESCRIPTION OF THE DRAWINGS

FIG. 1 is a flowchart of an example method for providing lights as part of a lighting plan in a software environment.

FIG. 2 is a sequence diagram of example steps for providing lights as part of a lighting plan.

FIG. 3 is a flowchart of an example method for providing a lighting plan for an identified segment group within a designated area.

FIG. 4 is an example system diagram including example components for providing lighting plans.

### DESCRIPTION OF THE EXAMPLES

Reference will now be made in detail to the present examples, including examples illustrated in the accompanying drawings. Wherever possible, the same reference numbers will be used throughout the drawings to refer to the same or like parts.

In an example, an option is provided within a program to provide lights for roads within a designated area of a city or municipality. A planning server can provide a lighting plan for running this functionality within a user device. The GUI within the user device can display a lighting plan for the roads within the designated area. The planning server within the user device can be used to provide lights for the roads within the designated area, for example.

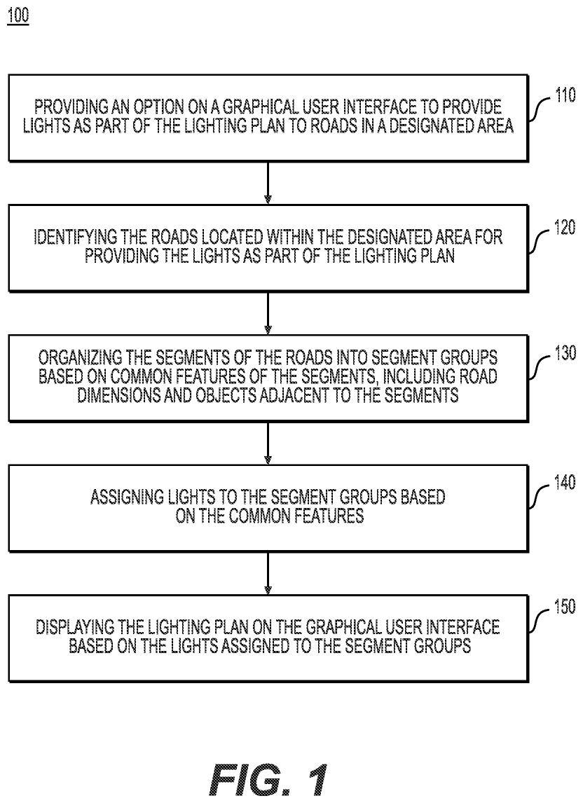

FIG. 1 is an example method 100 for providing lights to roads as part of a lighting plan. At stage 110, a system including a planning server can provide an option on the GUI to provide the lights as part of the lighting plan to the roads in the designated area. This can include providing a button on the GUI or a drop-down menu item. The button can cause the system to place lights on the roads according to the lighting plan.

At stage 120, the planning server can identify the roads to be provided with the lights according to the lighting plan within the designated area. The roads that are identified can be located within one or more cities or within one city. The roads can cover several miles or more within a city or municipality. For example, city limit data can be used to select the designated area. The roads within that designated area can be identified.

Alternatively, a user can also manually select the roads on the GUI. For example, the user can click one or more parts or draw a box around multiple areas on the GUI to select the roads. The user can also deselect areas that should be excluded from the plan, in an example.

At stage 130, the planning server can organize segments of the roads into segment groups based on common features of the segments. The common features can include road dimensions. The road dimensions the length, width, and curve of for each street within each segment group. The planning server determines at least one of length, width and curve for each street within each segment group. For example, segments can be set at a certain length, such as 100 feet. The width and curves during those 100 feet can be used to match against other similar road segments for purposes of grouping.

Other common features can include environmental data such as the traffic level of the segment groups. The traffic level can consist of pedestrians and vehicles travelling within the segment groups. The traffic level can also include objects adjacent to the segments such as buildings and signs. The traffic level can also include objects adjacent to the segments such as buildings and signs. Segment groups with a higher level of traffic than another segment group will require a different set of lights accordingly. The lighting plan for the fixtures can be provided to accommodate the higher level of traffic within a segment group. The lighting plan can include a specific number of lights and specific direction the lights are to be projected to accommodate for the higher traffic level within the segment group.

The common features can also include the level of crime that occurs in each segment group. The level of crime between segment groups can vary. Segment groups with higher levels of crime will require different lighting plans than other segment groups. The lighting plans of the segment groups with higher crime levels can be situated to provide more light on the crime occurring, thereby lower the level of crime as a result.

At stage 140, the planning server can assign the lights to the segment groups based on the common features. The planning server can assign the lights to the fixtures based on the road dimensions for each fixture. Moreover, the planning server can assign the lights according to a length, width and curve for each segment group on which the fixture is located. The planning server also assigns the lights according to a traffic level of the segment groups. The traffic level can include the vehicles and pedestrians passing thru the segment groups and the objects within the segment groups as well. Segment groups with higher traffic levels obtain different lighting arrangements than other segment groups to accommodate the higher traffic levels. Further, the planning server assigns the lights based on a level of crime for each segment group. The level of crime can be greater for some segment groups than others, thereby requiring different light fixtures to make the level of crime more visible for the police and law enforcement to prevent.

The planning server can also assign the lights according to the segment groups that are adjacent to each other. The distance and height of the neighboring segment groups can affect the type of lighting plan that is required for each segment group. The segment groups will require a lighting plan based factors such as object data from an adjacent segment group that could filter onto another segment group. Given these factors, the planning server can also determine whether to assign the lights either on only one side of a street or on both sides of the street for each segment group. In addition, the planning server can also determine a maximum and a minimum light intensity for the lights for each segment group.

At stage 150, the GUI displays the lighting plan for each of the segment groups based on the lighting plans that the planning server has assigned to the segment groups. Once the planning server has identified the roads, organized the roads into segment groups based on common features, and determined the lights to be assigned to the segment groups based on the common features, the GUI can display the lighting plan for each of the segment groups.

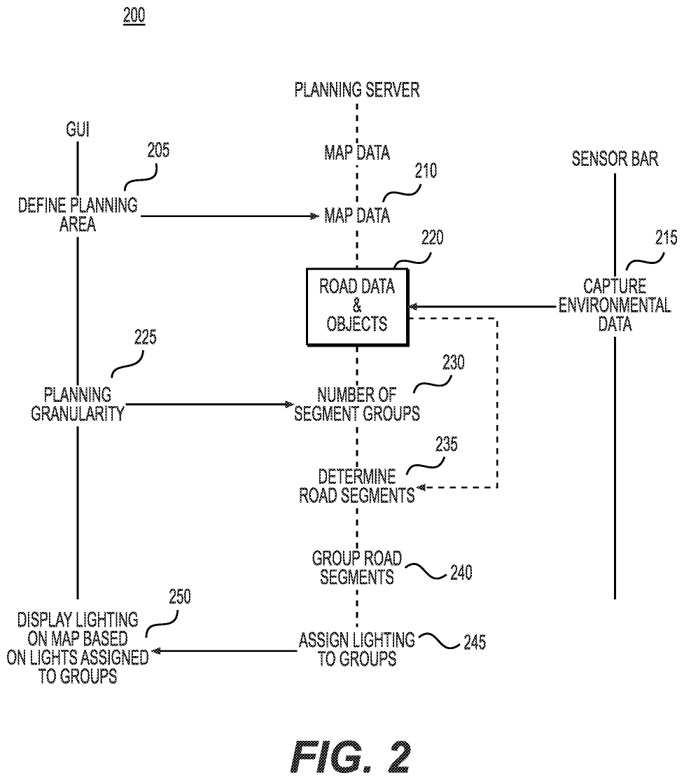

FIG. 2 is a sequence diagram 200 for determining and providing lighting plans by organizing roads into segment groups within a designated area. At stage 205, the GUI defines a planning area for the lighting plan. The planning server defines the planning area as part of the map data at stage 210. The planning server can identify the roads in the designated area to be used to assign the lights as part of the lighting plan. The map data can include the length, width, and curve for each segment for each segment group. The map data can also include determining which segments are adjacent to each other. Further, the map data can also include the traffic level and the level of crime for each segment group. Some segment groups can have higher levels of traffic and a greater level of crime than other segment groups, thereby requiring a different lighting plan as a result.

At stage 215, a sensor bar can also capture environmental data of the roads. The sensor bar can be mounted on a vehicle that physically travels through the planning area. The sensor bar can return environmental data for use within the system. The environmental data can also include the traffic level of the segment groups described above. The sensor bar can determine when some of the segment groups can have a greater level of traffic in relation to pedestrians and vehicles than other segment groups. The environment data can also include a level of crime for each segment group described above. The sensor bar can determine when one of the segment groups has a greater level of crime in comparison to the other segment groups. The sensor bar can provide the captured environmental data to the planning server with the road data and objects at stage 220. At stage 225, the GUI can provide a planning granularity for the lights as part of the lighting plan.

Further, at stage 230, the GUI can provide the planning granularity that is used to specify the number of segment groups. For example, the user can make selections on the GUI regarding granularity or processing time or can even explicitly specify a number of segment groups. Such inputs can be translated into how many segment groups are created. For example, 5000 different segments groups can take much more processing and time to organize than 100 segment groups, in an example. To achieve a specified number of segment groups, the planning server can change the required level of similarity needed between segments in order for them to be grouped together.

At stage 235, the planning server can determine the road segments using the road data and the adjacent objects obtained. The planning server provides the road data and the adjacent objects and the number of segment groups to group the road segments at stage 240. The planning server groups the roads into segment groups based on the common features of the segment groups. Moreover, the planning server organizes the roads into segment groups based on shared common features described above.

The planning server can assign the lighting to the segment groups at stage 245. After the planning server has grouped the road segments, the planning server assigns the lighting to the segment groups. The lighting can be assigned to the segment groups based on the road data such as the length, width, and curve of each segment and which segments are adjacent to each other. For example, different lighting fixtures are appropriate for different road widths and turns. In addition, the lighting can be assigned based on the environmental data (e.g., demographic information) such as the level of crime and the traffic for the segment groups. Further, the planning server can determine whether to assign lights on both sides of a street for each segment, or on just one side of the street for each of the segments. The planning server can also determine a maximum and a minimum light intensity for the lights for each segment group. The planning server can provide the assigned lighting to the various light fixtures within each segment groups after determining the type of lighting required for each light fixture. At stage 250, the GUI displays the lighting on a map based on the lights that are assigned to the segment groups.

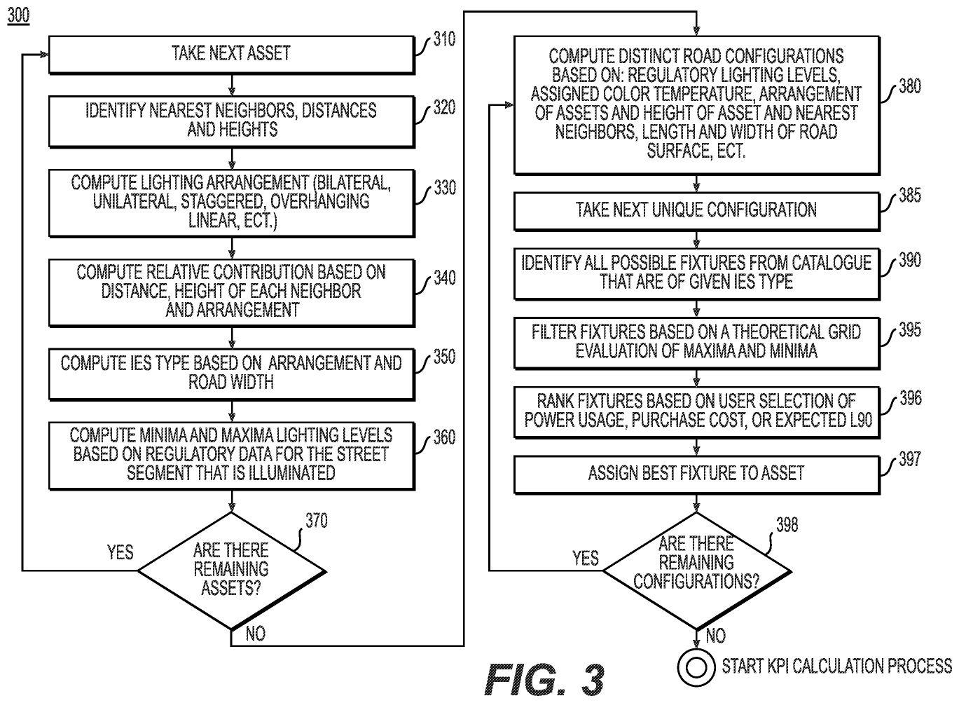

FIG. 3 shows another example flowchart for identifying the lights required for each lighting plan and providing the lights to each of the segment groups accordingly. Stages 310-360 can be used to determine which type of lights are assigned to the grouped segments. These stages can apply to the segment groups to reduce the number of analyzed segments. Alternatively, these stages can apply to some or all of the individual segments. Fixture locations can already be assigned to the grouped segments. Then specific assets can be chosen for those locations. Stages 380-398 can select the actual commercially available lights or other asset type to use. These stages are discussed in more detail below.

At stage 310, a next asset or fixture within a segment group among the segment groups can be identified. Assets can refer to lights, but other assets such as cameras or networking components are also possible. Fixtures may be referred to for convenience, but any type of asset can apply to these examples. The planning server can iterate through each fixture within the city. During the process, the planning server identifies the next fixture to determine the lights that are required for that fixture. At stage 320, the planning server identifies the nearest neighbors to the identified fixture. Moreover, the planning server can identify the distances and heights of nearest neighboring fixtures to further determine the type of lights required for the identified fixture. In addition, the planning server can also identify other object data such as buildings and signs that are closest to the identified fixture.

At stage 330, the planning server can compute the type of lighting arrangement required for the identified fixture. The lighting arrangement would be based on the lights required for the identified fixture given its nearby surroundings. Due to the nearby surroundings of the current fixture, the planning server can compute the lighting arrangement to be on one side of the street or on both sides of the street.

At stage 340, the planning server can compute a relative contribution of each of the nearest neighbors based on the distance, height, and the arrangement of each nearest neighbor onto the identified fixture. The planning server determines the relative contribution of the nearest neighboring fixture and object data such as the nearest neighboring building or sign. The relative contribution of the neighboring fixture and object data can enable the planning server to determine, for example, the angle of the lights required for the identified fixture. Other features can also include the number of lights and in what direction the lights should be projected.

At stage 350, the planning server can compute the illumination engineer society (IES) type light required for the identified fixture based on the arrangement of the nearest neighbors and the road width surrounding the identified fixture. An IES group can lay out the standard for the lights such has the shape and footprint of the lighting required for the fixture. The planning server can determine the distinct road configurations around the fixture. The planning server can determine the length, width and curve of the road configurations to determine how the lighting of the fixture is impacted.

The planning server can compute a maximum and a minimum light intensity for the fixture at stage 360. The planning server can compute the maximum and minimum light intensity required for the fixture according to the regulatory data. Moreover, the road configurations and the object data such as nearest neighboring fixtures and surrounding buildings and signs can allow the planning server to determine the maximum and minimum light intensity of the lights for the fixture. At stage 370, the planning server can determine if there are any remaining assets or fixtures in need of lighting. If the planning server determines that there is a remaining asset in need of lighting, the planning server can repeat the steps beginning at stage 310 for the next identified fixture to determine the lighting required.

At stage 380, the planning server can compute the distinct road configurations. The distinct road configurations can include regulatory lighting levels. The regulatory lighting levels can include the maximum and minimum intensity of the lights required for the fixture. The regulatory lighting levels can also include the assigned color temperature for the lighting required for the fixture. The planning server can determine the required color temperature of the lights for the fixture based on its nearby surroundings including environmental and object data. The road configurations can also include the arrangement of the fixture within the segment group and the height of the fixture.

The planning server can determine the height of the fixture and its relationship to the street and segment group it is located within when determining the appropriate lighting for the fixture. Moreover, the planning server determining how tall the fixture is and whether the neighboring fixtures hinder or enhance the fixture can enable the planning server to determine the proper lighting for the fixture. The planning server can also determine the length, width and curve of the street or road on which the fixture is positioned to determine the appropriate lighting as well.

The above determinations can enable the planning server to determine various detailed features of the light. The detailed features can include the number of lights, the angle of the lights, and the direction at which the lights are projected. For instance, if the fixture is greater in height than the neighboring features and nearby buildings, the planning server can determine that the fixture requires fewer lights. In contrast, the planning server can ultimately determine that the identified fixture requires more lights that project outward to compensate for its smaller height in comparison to the nearest fixtures nearby the identified fixture.

At stage 385, the planning server can determine and take the next unique configuration of lights that are available to provide to the fixture. Based on the road configurations, the height of the fixture, and the height of the nearest neighboring fixtures, the planning server can determine the unique configuration or lighting plan that is required for the fixture based on the lighting plans available within the lighting database. The lighting database within the user device can include configurations of various lighting plans that the planning server can select to provide for the identified fixture.

At stage 390, the planning server can thereby use the lighting database to identify all possible lighting plans that have the given IES type needed for the fixture. The planning server can determine the required IES type for the identified fixture based on the road configurations such as the length, width and curve of the road on which the fixture is located. In addition, the planning server also determines the required IES type according to the arrangement of the fixture with respect to the nearest neighboring fixtures, other object data, and environmental data such as traffic and crime levels. Accordingly, the planning server can identify all possible available lights of the required IES type within the lighting database. At stage 395, the planning server filters the lighting plans based on a theoretical grid evaluation of the maximum and minimum light levels. The planning server filters the lighting plans according to the maximum and minimum lighting levels to further identify the lighting plan with the maximum and minimum lighting levels needed for the fixture.

At stage 396, the planning server can rank the lighting plans within the lighting database based on a user selection of power usage or purchase cost or expected L90 (expected ninety percent of the light output). The user selection for power usage and purchase can refer to the amount of potential use of the light and the cost of the lights for the fixture. According to the rankings of the lighting plans within the lighting database, the planning server can identify which of the lighting plans can be suited for the fixture based on their rankings within the lighting database.

The planning server can then assign best fixture or lighting plan to the fixture at stage 397. Based on the rankings of the lighting plans, the planning server determines which lighting plan would best align with the fixture given the road configurations and surroundings of the fixture and the required IES type light needed for the fixture. The planning server can then provide the lighting to the fixture after deciding which lighting plan would be best suited for the fixture. At stage 398, the planning server can determine if there are any remaining fixtures or lighting plans. If the planning server determines that there are remaining lighting plans to assign, then the planning server can repeat the process starting at stage 380 for another fixture. In the alternative, the planning server can start a KPI (key performance indicator) calculation process of creating grid measurements and identifying if any missing fixtures exist within the group segments when it determines that that there are no current lighting plans available in the lighting database.

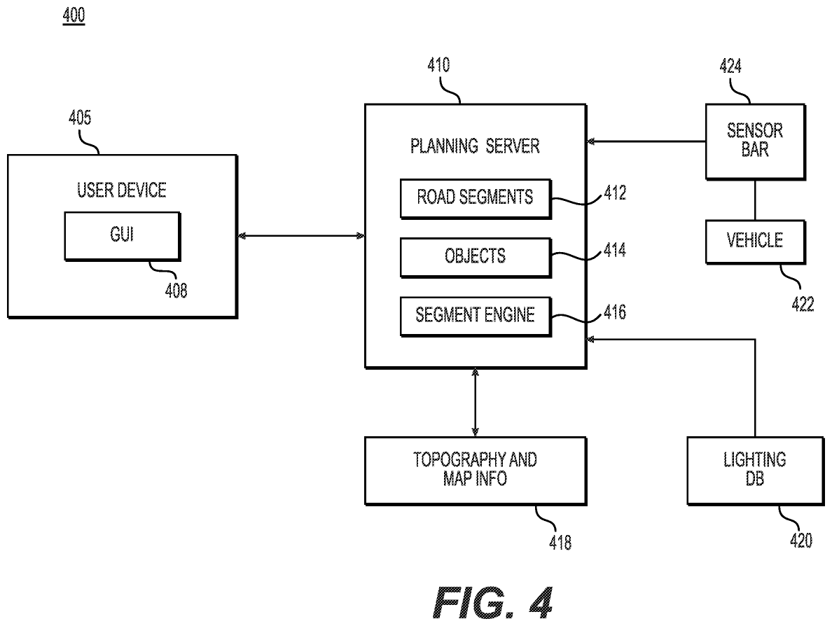

FIG. 4 includes an exemplary diagram of a system 400 in accordance with an example. A user device 405 can include a GUI 408. The GUI 408 can be used to create and display a design layout.

The user device 405 can be any processor-based device, such as a personal computer, laptop, tablet, or cell phone. It can also include a planning server in one example. The system 400 can also include a planning server 410. The planning server 410 can be part of the user device 405 or be coupled to the user device 405. The planning server 410 can include road segments 412. The planning server 410 can identify and provide the road segments 412 that require lighting plans. The planning server 410 also includes objects 414 and a segment engine 416. The objects 414 can be the objects identified within the identified road segments 412 that can affect the type of lighting plans that can be provided to light fixtures within the road segments 412. The segment engine 416 can be used to organize the identified road segments into a plurality of segment groups. The fixtures to be provided with the lights can be found within the segment groups.

The planning server 410 is coupled to the topography and map info 418 of the designated area. The topography and map info 418 can include the roads that are organized into segment groups. The topography and map info 418 can also include the road configurations of the segment groups such as the length, width and curve of the roads for each segment group. Further, the topography and map info 418 can also include the environmental data such as the traffic level and the level of crime within the segment groups. A lighting database 420 comprising a plurality of lighting plans can be coupled to the planning server 410. The lighting database 420 can also include the IES lighting types that are required for each fixture. After the planning server 410 determines the lighting plan required for a fixture, the planning server 410 can access the lighting database 420 to obtain the lighting plan required for the fixture and provide the lighting plan to the fixture.

The lighting database 420 can be implemented on any type of computing device such as a personal computer, laptop, tablet, or cell phone. In one example, the lighting database 420 is part of the user device 405. In another example, the lighting database 420 is remotely accessible by the user device 405, such as over a network. The network can be a local area network, an enterprise network, or the Internet.

A vehicle 422 can be part of the system 400 and can also be coupled to the planning server 410 and user device 405. The vehicle 422 can contribute to the traffic level of one or more group segments and provide part of the topography and map info 418. A sensor bar 424 can be coupled to the vehicle 422 and the planning server 410. The sensor bar 424 can identify the environmental data occurring within the segment groups. Moreover, the sensor bar 424 can identify the traffic level occurring within a segment group. Further, the sensor bar 424 can also identify a level of crime that may occur within each segment group. The sensor bar 424 can also contribute to the topography and map info 418 that enables the planning server to identify the proper lighting plan for each fixture. In addition, the sensor bar 424 can also enable the planning server 410 to identify the objects 414 within the segment groups.

Other examples of the disclosure will be apparent to those skilled in the art from consideration of the specification and practice of the examples disclosed herein. Though some of the described methods have been presented as a series of steps, it should be appreciated that one or more steps can occur simultaneously, in an overlapping fashion, or in a different order. The order of steps presented are only illustrative of the possibilities and those steps can be executed or performed in any suitable fashion. Moreover, the various features of the examples described here are not mutually exclusive. Rather any feature of any example described here can be incorporated into any other suitable example. It is intended that the specification and examples be considered as exemplary only, with a true scope and spirit of the disclosure being indicated by the following claims.

What is claimed is:

1. A method for creating a lighting plan comprising:
identifying one or more roads within a designated area for providing lights as part of the lighting plan;
organizing segments of the roads into segment groups based on common features of the segments, including road dimensions and objects adjacent to the segments;
assigning lights to the segment groups based on the common features; and
displaying the lighting plan on a graphical user interface (“GUI”) based on the lights assigned to the segment groups.

2. The method of claim 1, wherein the common features are based on determining at least one of a length, width and curve for each segment.

3. The method of claim 1, further comprising:
organizing the segments into the segment groups based on traffic level as one of the common features, wherein the lights are determined based on the traffic level for each segment group.

4. The method according to claim 1, further comprising:
assigning the lights based on a level of crime for each segment group.

5. The method according to claim 1, further comprising:
determining segments that are adjacent to each other as part of determining the lights for the segment groups.

6. The method according to claim 1, further comprising:
determining whether to provide lights on both sides of a street for each segment group.

7. The method according to claim 1, further comprising:
determining a maximum and a minimum light intensity for the lights for each segment group using the common features.

8. A system for providing a lighting plan, including:
a database that stores recommendations of a lighting plan;
a processor that executes instructions to perform stages comprising:
identifying roads located within a designated area for providing lights as part of the lighting plan;
organizing segments of the roads into segment groups based on common features of the segments, including road dimensions and objects adjacent to the segments;
assigning the lights to the segment groups based on the common features; and
displaying the lighting plan on a graphical user interface (“GUI”) based on the lights assigned to the segment groups.

9. The system of claim 8, wherein the common features are based on determining at least one of a length, width and curve for each segment.

10. The system of claim 8, wherein the stages further comprise:
organizing the segments into the segments into the segment groups based on traffic level as one of the common features wherein the lights are determined based on the traffic level for each segment group.

11. The system of claim 8, wherein the stages further comprise:
assigning the lights based on a level of crime for each segment group.

12. The system of claim 8, wherein the stages further comprise:
determining the segments that are adjacent to each other as part of determining the lights for the segment groups.

13. The system of claim 8, wherein the stages further comprise:
determining whether to provide the lights on both sides of a street for each segment group.

14. The system of claim 8, wherein the stages further comprise:
determining a maximum and a minimum light intensity for the lights for each segment group using the common features.

15. A non-transitory computer-readable medium including instructions for providing a lighting plan, a processor executing the instructions to perform stages comprising:
identifying one or more roads within a designated area for providing lights as part of the lighting plan;
organizing segments of the roads into segment groups based on common features of the segments, including road dimensions and objects adjacent to the segments;
assigning lights to the segment groups based on the common features; and
displaying the lighting plan on a graphical user interface (“GUI”) based on the lights assigned to the segment groups.

16. The non-transitory computer-readable medium of claim 15, wherein the common features are based on determining at least one of a length, width and curve for each segment.

17. The non-transitory computer-readable medium of claim 15, the stages further comprising:
organizing the segments into the segment groups based on traffic level as one of the common features, wherein the lights are determined based on the traffic level for each segment group.

18. The non-transitory computer-readable medium of claim 15, the stages further comprising:
assigning the lights based on a level of crime for each segment group.

19. The non-transitory computer-readable medium of claim 15, the stages further comprising:
determining segments that are adjacent to each other as part of determining the lights for the segment groups.

20. The non-transitory computer-readable medium of claim 15, the stages further comprising:
determining whether to provide lights on both sides of a street for each segment group.
